(19) United States
(12) Patent Application Publication
(10) Pub. No.: US 2026/0026341 A1
(43) Pub. Date: Jan. 22, 2026

(54) SUBSTRATE PACKAGE AND METHOD OF MANUFACTURING SEMICONDUCTOR PACKAGE

(71) Applicant: Samsung Electronics Co., Ltd., Suwon-si (KR)

(72) Inventors: Taejae PARK, Suwon-si (KR); Chaein MOON, Suwon-si (KR); Inkyu PARK, Daejeon (KR); Hyeonseok HAN, Daejeon (KR); Cheolmin KIM, Daejeon (KR); Sunchul KIM, Suwon-si (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 19/020,127

(22) Filed: Jan. 14, 2025

(30) Foreign Application Priority Data
Jul. 16, 2024 (KR) 10-2024-0093951

(51) Int. Cl. H01L 23/36; H01L 23/00; H01L 23/498

(52) U.S. Cl. CPC H01L 23/36; H01L 23/49838; H01L 23/49894; H01L 24/16; H01L 24/81; H01L 2224/16227; H01L 2224/81234

(57) ABSTRACT

Provided is a semiconductor package including a substrate including a body having a first surface and a second surface, the first surface and the second surface opposite to each other, a plurality of interconnection patterns arranged in a vertical direction within the body, the plurality of interconnection patterns including upper terminals on the first surface and lower terminals on the second surface, and an induction heating structure within the body, and the induction heating structure spaced apart from the plurality of interconnection patterns, an upper protective layer on the first surface of the substrate and the upper protective layer including first openings respectively exposing the upper terminals, a semiconductor chip on the upper protective layer, and the semiconductor chip including connection pads.

### CROSS-REFERENCE TO RELATED APPLICATION(S)

This application claims benefit of priority to Korean Patent Application No. 10-2024-0093951, filed on Jul. 16, 2024 in the Korean Intellectual Property Office, the inventive concepts of which is incorporated herein by reference in its entirety.

### BACKGROUND

Some example embodiments of the inventive concepts relate to a semiconductor package and a method of manufacturing the semiconductor package.

As semiconductor chips continue to become more highly integrated, the number of connection pads on semiconductor chips continues to increase, and accordingly the intervals between the connection pads becomes smaller. Highly integrated semiconductor chips may be mounted on a substrate in a flip chip bonding method by reflowing solder bumps and fusing the solder bumps to an interconnection pattern on the substrate. Heat applied to the solder bumps during the reflow process may cause thermal damage to the substrate and/or the semiconductor chip.

### SUMMARY

Some example embodiments of the inventive concepts provide a semiconductor package and a method of manufacturing the semiconductor package having improved reliability.

According to some example embodiments of the inventive concepts, provided is a semiconductor package, the semiconductor package including a substrate including a body having a first surface and a second surface, the first surface and the second surface opposite to each other, a plurality of interconnection patterns arranged in a vertical direction within the body, the plurality of interconnection patterns including upper terminals on the first surface and lower terminals on the second surface, and an induction heating structure within the body, and the induction heating structure spaced apart from the plurality of interconnection patterns, an upper protective layer on the first surface of the substrate and the upper protective layer including first openings respectively exposing the upper terminals, a semiconductor chip on the upper protective layer, and the semiconductor chip including connection pads, upper connection bumps on the first openings of the upper protective layer, and the upper connection bumps electrically connecting the connection pads and the upper terminals, a lower protective layer on the second surface of the substrate, and the lower protective layer including second openings respectively exposing the lower terminals and a through-hole exposing at least a portion of the induction heating structure, and lower connection bumps on the second openings of the lower protective layer, and the lower connection bumps electrically connected to the lower terminals. The induction heating structure includes at least one lower pad exposed through the through-hole, and a first width of the at least one lower pad in a horizontal direction is greater than a second width of each of the lower terminals in the horizontal direction.

According to some example embodiments of the inventive concepts, provided is a semiconductor package, the semiconductor package including a substrate including a body including a first surface and a second surface, the first surface and the second surface opposite to each other, a plurality of interconnection patterns arranged in a vertical direction within the body, the plurality of interconnection patterns including upper terminals on the first surface and lower terminals on the second surface, and an induction heating structure within the body, and the induction heating structure spaced apart from the plurality of interconnection patterns, an upper protective layer on the first surface of the substrate, a semiconductor chip on the upper protective layer, and the semiconductor chip including connection pads, upper connection bumps between the substrate and the semiconductor chip, and the upper connection bumps electrically connecting the connection pads and the upper terminals, and lower connection bumps on the second surface of the substrate, and the lower connection bumps electrically connected to the lower terminals. The induction heating structure includes at least one lower pad overlapping a lowermost interconnection pattern among the plurality of interconnection patterns in a horizontal direction, the at least one lower pad is electrically insulated from the plurality of interconnection patterns, and a width of the at least one lower pad in the horizontal direction is greater than a width of each of the lower terminals in the horizontal direction.

According to some example embodiments, provided is a method of manufacturing a semiconductor package, the method including preparing a substrate including a first surface and a second surface, the first surface and the second surface opposite to each other, and the first surface including upper terminals, the second surface including lower terminals, at least one lower pad, and a planar area of the lower pad is greater than a planar area of each of the lower terminals, preparing a semiconductor chip including connection pads and solder bumps on the connection pads, respectively, attaching the semiconductor chip on the first surface of the substrate so that the solder bumps are attached to the upper terminals, disposing a coil structure on the second surface of the substrate, the coil structure adjacent to the at least one lower pad, applying an alternating current to the coil structure so that an alternating magnetic field of 500 kHz or less is generated inside the coil structure, inductively heating the at least one lower pad by the alternating magnetic field, and reflowing the solder bumps by heat conducted from the at least one lower pad.

### BRIEF DESCRIPTION OF DRAWINGS

The above and other aspects, features, and advantages of the present disclosure will be more clearly understood from the following detailed description, taken in conjunction with the accompanying drawings:

FIG. 1A is a cross-sectional view of a semiconductor package according to some example embodiments, and FIG. 1B is a plan view taken along line I-I′ of FIG. 1A;

FIG. 2 is a cross-sectional view of a semiconductor package according to some example embodiments;

FIG. 3 is a cross-sectional view of a semiconductor package according to some example embodiments;

FIG. 4A is a cross-sectional view of a semiconductor package according to some example embodiments, and FIG. 4B is a plan view taken along line II-II′ of FIG. 4A;

FIG. 5 is a cross-sectional view of a semiconductor package according to some example embodiments;

FIG. 6 is a cross-sectional view of a semiconductor package according to some example embodiments;

FIG. 7 is a cross-sectional view of a semiconductor package according to some example embodiments;

FIGS. 8A to 8C are drawings for illustrating a method of manufacturing a semiconductor package according to some example embodiments; and

FIG. 9 is a schematic cross-sectional view of a test substrate used in an experimental example.

### DETAILED DESCRIPTION

Hereinafter, with reference to the accompanying drawings, preferred embodiments will be described as follows. Unless otherwise specified, in this specification, terms such as ‘upper,’ ‘upper surface,’ ‘lower,’ ‘lower surface,’ ‘side’ and the like are based on the drawings, and actually, may vary depending on the direction in which the components are disposed.

In addition, ordinal numbers such as “first,” “second,” “third,” or the like may be used as labels for specific elements, step portions, directions, or the like to distinguish various elements, step portions, directions, or the like from each other. Terms that are not described using “first,” “second,” or the like in the specification may still be referred to as “first” or “second” in the claims. In addition, terms referenced by a particular ordinal number (e.g., “first” in a particular claim) may be described elsewhere with a different ordinal number (e.g., “second” in the specification or another claim).

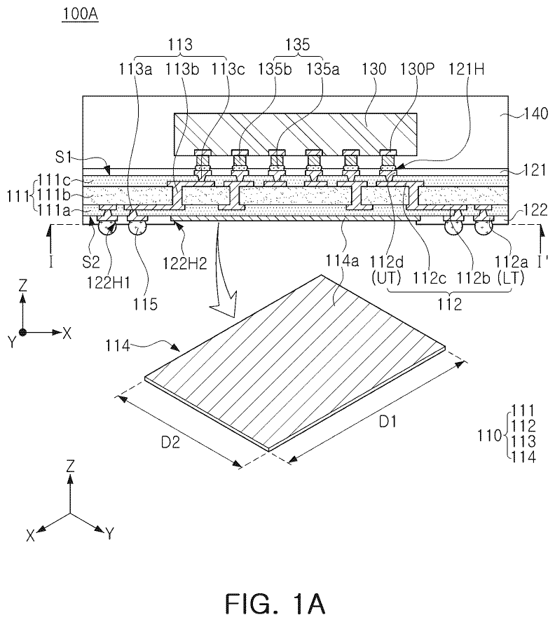

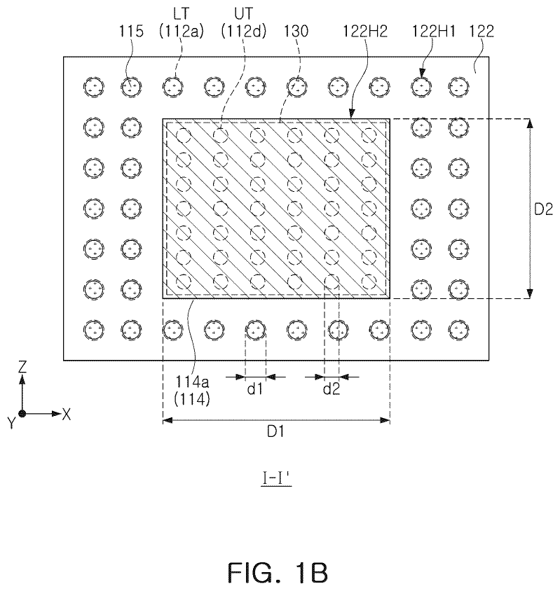

FIG. 1A is a cross-sectional view of a semiconductor package 100A according to some example embodiments, FIG. 1B is a plan view of the semiconductor package 100 of FIG. 1A, and FIG. 1C is a partially enlarged view of region ‘A’ of FIG. 1A.

Referring to FIGS. 1A and 1B, the semiconductor package 100A of some example embodiments may include a substrate 110, lower connection bumps 115, a semiconductor chip 130, and upper connection bumps 135. According to some example embodiments, the semiconductor package 100A may further include an upper protective layer 121 and a lower protective layer 122.

The substrate 110 is a support substrate on which the semiconductor chip 130 is mounted, and may be a substrate for a semiconductor package, including a printed circuit board (PCB), a ceramic substrate, a glass substrate, a tape interconnection substrate, and the like. However, example embodiments are not limited thereto. The substrate 110 may include a body 111, an interconnection pattern 112, an interconnection via 113, and an induction heating structure 114.

The body 111 has a first surface S1 and a second surface S2, opposite to each other, and may include a plurality of insulating layers 111a, 111b, and 111c stacked in a vertical direction (Z-direction). The plurality of insulating layers 111a, 111b, and 111c may include an insulating material, for example, a thermosetting resin such as an epoxy resin, a thermoplastic resin such as polyimide, or a prepreg containing inorganic fillers and/or glass fibers (glass cloth, glass fabric), Ajinomoto Build-up Film (ABF), Frame Retardant 4 (FR-4), and the like. However, example embodiments are not limited thereto. In some example embodiments, the insulating layer 111b (hereinafter, referred to as a ‘core insulating layer’) disposed in the middle of the plurality of insulating layers 111a, 111b, and 111c may be formed using, for example, a copper clad laminate (CCL), an unclad copper clad laminate (Unclad CCL), a glass substrate, a ceramic substrate, or the like. However, example embodiments are not limited thereto. A thickness of the core insulating layer 111b may be greater than a thickness of each of the insulating layers 111a and 111c stacked below and above the core insulating layer 111b. The plurality of insulating layers 111a, 111b, and 111c may be provided in numbers greater or lesser than those shown in the drawing. Depending on the process, a boundary between the plurality of insulating layers 111a, 111b, and 111c may not be clear.

The interconnection pattern 112 may be configured to form an electrical connection path for rewiring the connection pads 130P of the semiconductor chip 130. The interconnection pattern 112 may include a plurality of interconnection patterns 112a, 112b, 112c, and 112d arranged in a vertical direction (Z-direction) within the body 111. The lowermost interconnection pattern 112a among the plurality of interconnection patterns 112a, 112b, 112c, and 112d may include lower terminals LT on the second surface S2. The uppermost interconnection pattern 112d among the plurality of interconnection patterns 112a, 112b, 112c, and 112d may include upper terminals UT on the first surface S1. The plurality of interconnection patterns 112a, 112b, 112c, and 112d may include at least one metal or an alloy of two or more metals selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe). However, example embodiments are not limited thereto.

The interconnection via 113 may extend in a vertical direction (Z-direction) within the body 111 to electrically connect a plurality of interconnection patterns 112a, 112b, 112c, and 112d to each other. The interconnection via 113 may include a plurality of interconnection vias 113a, 113b, and 113c arranged in the vertical direction (Z-direction). The plurality of interconnection vias 113a, 113b, and 113c may include at least one metal or an alloy of two or more metals selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe). However, example embodiments are not limited thereto. The plurality of interconnection vias 113a, 113b, and 113c may have a shape of a filled via in which a metal material is filled inside a via hole or a shape of a conformal via in which a metal material is formed along an inner wall of the via hole. In some example embodiments, an interconnection via 113b (hereinafter, referred to as a ‘core via’) disposed in the middle of the plurality of interconnection vias 113a, 113b, and 113c may have a form in which a via hole penetrating the core insulating layer 111b is completely filled with a conductive material. In some example embodiments, the core via 113b may have a form in which a conductive material is conformally formed along a wall of the via hole, and an inner space thereof is filled with an insulating material such as an epoxy resin. A height of the core via 113b may be greater than a height of each of the interconnection vias 113a and 113c disposed below and above the core via 113b. In some example embodiments, the lower interconnection via 113a and the upper interconnection via 113c may have a shape with a side surface tapered toward the core via 113b, respectively.

The induction heating structure 114 may be disposed within the body 111, and may be electrically insulated from the interconnection pattern 112. The induction heating structure 114 may include a material similar to the interconnection pattern 112, for example, at least one metal or an alloy of two or more metals selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe). However, example embodiments are not limited thereto.

In some example embodiments, the induction heating structure 114 may be configured to be selectively inductively heated by a low-frequency alternating current or an alternating magnetic field of about 500 kHz or less, so that heat required for reflow of the upper connection bumps 135, in particular, the solder portion 135a may be conducted to the upper terminals UT of fine pitch. Therefore, by limiting and/or preventing the lower terminals LT and the upper terminals UT from being inductively heated and heating the upper terminals UT to a temperature required for reflow, for example, in the range of 200° C. to 300° C., thermal damage during the reflow process may be reduced and/or minimized.

The induction heating structure 114 may include at least one lower pad 114a disposed on the second surface S2. At least one lower pad 114a may be spaced apart from a plurality of interconnection patterns 112a, 112b, 112c, and 112d and a plurality of interconnection vias 113a, 113b, and 113c. At least one lower pad 114a may overlap the lowermost interconnection pattern 112a in a horizontal direction (X- and Y-directions). A planar or substantially planar area of at least one lower pad 114a may be greater than a planar or substantially planar area of each of the lower terminals LT.

A thickness of at least one lower pad 114a in a vertical direction (Z-direction) may be equal to or substantially equal to a thickness of each of the lower terminals LT in the vertical direction (Z-direction). In some example embodiments, to improve induction heating efficiency, the thickness of at least one lower pad 114a may be greater than the thickness of each of the lower terminals LT.

At least one lower pad 114a may overlap the upper terminals UT and the upper connection bumps 135 in the vertical direction (Z-direction). In a planar view, at least one lower pad 114a may have a circular or polygonal plate shape covering most of the upper terminals UT and connection pads 130P.

At least one lower pad 114a may have a width or diameter, greater than those of the lower terminals LT and the upper terminals UT. For example, a width (D1 and D2) of at least one lower pad 114a in a horizontal direction (X- and Y-directions) may be greater than a width (d1) of each of the lower terminals LT in the horizontal direction (X- and Y-directions). In addition, the width (D1 and D2) of at least one lower pad 114a may be greater than a width (d2) of each of the upper terminals UT in the horizontal direction (X- and Y-directions). The width (d2) of each of the upper terminals UT may be smaller than the width (d1) of each of the lower terminals LT.

A width D1 of at least one lower pad 114a in a first horizontal direction (X-direction) and a width D2 of at least one lower pad 114a in a second horizontal direction (Y-direction) may be substantially the same, but example embodiments are not limited thereto. In some example embodiments, the width D1 of at least one lower pad 114a in a first horizontal direction (X-direction) may be greater than the width D2 thereof in a second direction (Y-direction), and a minimum width D2 of at least one lower pad 114a may be greater than a maximum width (d1) of each of the lower terminals LT.

The width (D1 and D2) of at least one lower pad 114a may be about 1000 μm or more, for example, within a range of about 1000 μm to about 2000 μm, about 1100 μm to about 2000 μm, about 1200 μm to about 2000 μm, about 1300 μm to about 2000 μm, about 1300 μm to about 1800 μm, about 1300 μm to about 1600 μm, about 1300 μm to about 1500 μm, and the like. When the width (D1 and D2) of at least one lower pad 114a is less than about 1000 μm, the at least one lower pad 114a may not be inductively heated to a temperature capable of sufficiently reflowing the solder bump 135a by a low-frequency alternating magnetic field of about 500 kHz or less.

The width (d1) of each of the lower terminals LT may be about 400 μm or less, for example, about 100 μm to about 400 μm, about 200 μm to about 400 μm, about 300 μm to about 400 μm, about 1300 μm to about 2000 μm, about 1300 μm to about 1800 μm, about 1300 μm to about 1600 μm, about 1300 μm to about 1500 μm, and the like. When the width (d1) of each of the lower terminals LT exceeds about 400 μm, the lower terminals LT may be heated together with the at least one lower pad 114a by a low-frequency alternating magnetic field of about 500 kHz or less, which may cause thermal damage.

The width (d2) of each of the upper terminals UT may be about 100 μm or less, for example, within a range of about 10 μm to about 100 μm, about 30 μm to about 100 μm, about 50 μm to about 100 μm, about 70 μm to about 100 μm, and the like.

Lower connection bumps 115 may be disposed on the second surface S2 of the substrate 110. In some example embodiments, the lower connection bumps 115 may be disposed on openings 122H1 of the lower protective layer 122, and may be electrically connected to the corresponding lower terminals LT, respectively. The lower connection bumps 115 may electrically connect the semiconductor package 100A to an external device such as a module substrate, a main board, or the like. The lower connection bumps 115 may include a solder ball and/or a conductive pillar. The lower connection bumps 115 may have a flip-chip connection structure having a grid array such as a pin grid array, a ball grid array, or a land grid array, for example. The lower connection bumps 115 may be electrically connected to an interconnection pattern 112 of the substrate 110 through the lower terminals LT of the substrate 110.

In some example embodiments, an upper protective layer 121 may be disposed on the first surface S1 of the substrate 110. The upper protective layer 121 may have first openings 121H respectively exposing the upper terminals UT. The lower protective layer 122 may be disposed on the second surface S2 of the substrate 110. The lower protective layer 122 may have second openings 122H1 respectively exposing the lower terminals LT. In some example embodiments, the lower protective layer 122 may further have a through-hole 122H2 exposing at least a portion of the induction heating structure 114. To improve induction heating efficiency, the through-hole 122H2 of the lower protective layer 122 may expose at least a portion of the lower pad 114a of the induction heating structure 114. The upper protective layer 121 and the lower protective layer 122 may be formed using a solder resist. According to some example embodiments, the upper protective layer 121 and the lower protective layer 122 may be formed as a non-solder mask defined (NSMD) structure entirely exposing the upper terminals UT and the lower terminals LT, respectively.

The semiconductor chip 130 may include a semiconductor wafer and an integrated circuit (IC) formed of a semiconductor element such as silicon or germanium, or a compound semiconductor such as silicon carbide (SiC), gallium arsenide (GaAs), indium arsenide (InAs), and indium phosphide (InP). However, example embodiments are not limited thereto. The semiconductor chip 130 may be a bare semiconductor chip without a separate bump or wiring layer formed, but the example embodiment is not limited thereto., and may also be a package-type semiconductor chip. The semiconductor chip 130 may include a logic circuit such as a central processor (CPU), a graphics processor (GPU), a field programmable gate array (FPGA), an application processor (AP), a digital signal processor, an encryption processor, a microprocessor, a microcontroller, an analog-to-digital converter, an application-specific IC (ASIC), or the like, or a memory circuit including a volatile memory such as a dynamic RAM (DRAM), a static RAM (SRAM), or the like, and a non-volatile memory such as a phase change RAM (PRAM), a magnetic RAM (MRAM), a resistive RAM (RRAM), a flash memory, or the like. However, example embodiments are not limited thereto.

The semiconductor chip 130 may be disposed on the first surface S1 of the substrate 110 and/or the upper protective layer 121. The semiconductor layer 130 may include connection pads 130P connected to an integrated circuit therein. The connection pads 130P may be electrically connected to the interconnection pattern 112 of the substrate 110 through upper connection bumps 135.

The upper connection bumps 135 may be disposed on the first surface S1 of the substrate 110. In some example embodiments, the upper connection bumps 135 may be disposed on the first openings 121H of the upper protective layer 121, and may electrically connect the corresponding connection pads 130P and the upper terminals UT, respectively. The upper connection bumps 135 may include a solder portion 135a and a pillar portion 135b. The solder portion 135a (or referred to as a ‘solder bump’) may include tin (Sn), indium (In), bismuth (Bi), antimony (Sb), copper (Cu), silver (Ag), zinc (Zn), lead (Pb), and/or an alloy thereof (e.g., Sn—Ag—Cu). However, example embodiments are not limited thereto. The pillar portion 135b may include, for example, copper (Cu) or an alloy of copper (Cu). Depending on the embodiment, the upper connection bumps 135 may include only the solder portion 135a. In some example embodiments, an underfill layer surrounding the upper connection bumps 135 may be disposed between the semiconductor chip 130 and the substrate 110. The underfill layer may have a capillary underfill (CUF) structure or a molded underfill (MUF) structure. According to some example embodiments, the solder portion 135a of the upper connection bumps 135 may be indirectly heated by heat conducted from the induction heating structure 114, thereby reducing and/or minimizing thermal damage of surrounding elements.

In some example embodiments, the semiconductor chip 120 may be encapsulated by a mold layer 140. The mold layer 140 may cover at least a portion of the semiconductor chip 120 on the first surface S1 of the substrate 110. The mold layer 140 may include an insulating resin such as an epoxy molding compound (EMC).

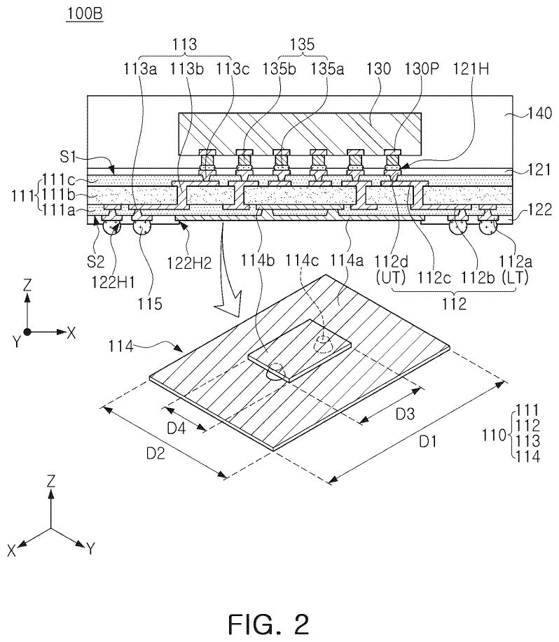

FIG. 2 is a cross-sectional view of a semiconductor package 100B according to some example embodiments.

Referring to FIG. 2, the semiconductor package 100B of some example embodiments may have the same or similar features as those described with reference to FIGS. 1A to 1B, except that the induction heating structure 114 further includes at least one upper pad 114b and at least one thermal conduction via 114c. The induction heating structure 114 may further include at least one upper pad 114b disposed on at least one lower pad 114a, and at least one thermal conduction via 114c connecting at least one lower pad 114a and at least one upper pad 114b.

The upper pad 114b may overlap at least one of the other interconnection patterns 112b, 112c, and 112d on a lowermost interconnection pattern 112a in the horizontal direction (X- and Y-directions). For example, the upper pad 114b may be disposed on the same level as the interconnection pattern 112b, adjacent to the lowermost interconnection pattern 112a in the vertical direction (Z-direction).

The upper pad 114b may include a plurality of upper pads spaced apart from each other in the horizontal direction (X- and Y-directions) and/or vertical direction (Z-direction). The upper pad 114b may be formed to have a smaller size than the lower pad 114a. For example, a width D3 of the upper pad 114b in the first horizontal direction (X-direction) may be smaller than the width D1 of the lower 114a in the first horizontal direction (X-direction), and a width D4 of the upper pad 114b in the second horizontal direction (Y-direction) may be smaller than the width D2 of the lower pad 114a in the second horizontal direction (Y-direction). The widths D3 and D4 of the upper pad 114b may be less than about 1000 μm, but example embodiments are not limited thereto. Depending on the design of the interconnection pattern 112, the upper pad 114b may be formed to have a size similar to that of the lower pad 114a.

The thermal conduction via 114c may include a plurality of thermal conduction vias spaced apart from each other in the horizontal direction (X- and Y-directions) and/or vertical direction (Z-direction). The thermal conduction via 114c may be formed to have a larger size than the interconnection via 113. For example, a diameter of the thermal conduction via 114c may be larger than a diameter of the interconnection via 113. The thermal conduction via 114c may connect the lower pad 114a and the upper pad 114b, thereby improving the thermal conductivity efficiency.

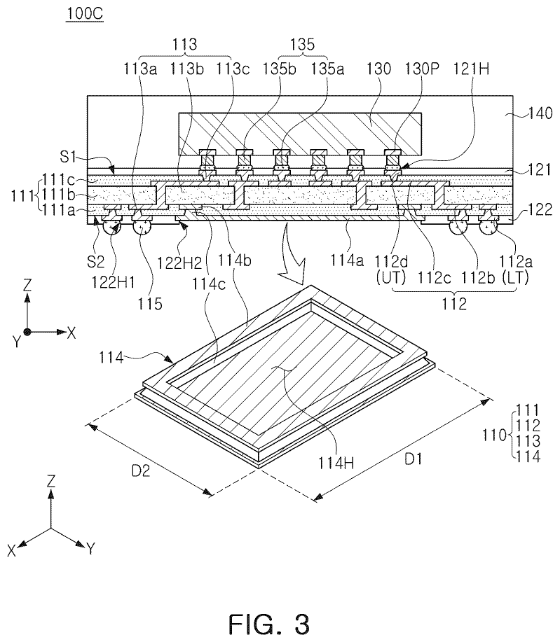

FIG. 3 is a cross-sectional view of a semiconductor package 100C according to some example embodiments.

Referring to FIG. 3, the semiconductor package 100C of some example embodiments may have the same or similar features as those described with reference to FIGS. 1A to 2, except that the induction heating structure 114 includes a patterned upper pad 114b and a thermal conduction via 114c. In some example embodiments, the upper pad 114b and the thermal conduction via 114c may be patterned in any shape according to the design of the interconnection pattern 112, e.g., along a region in which the interconnection pattern 112 is not disposed. For example, the upper pad 114b may have a circular or polygonal ring shape with a hollow portion 114H. However, example embodiments are not limited thereto. In some example embodiments, the upper pad 114b may have a rectangular ring shape extending along an edge of the lower pad 114a. In addition, the thermal conduction via 114c may extend along the upper pad 114b, and have a shape similar to that of the upper pad 114b.

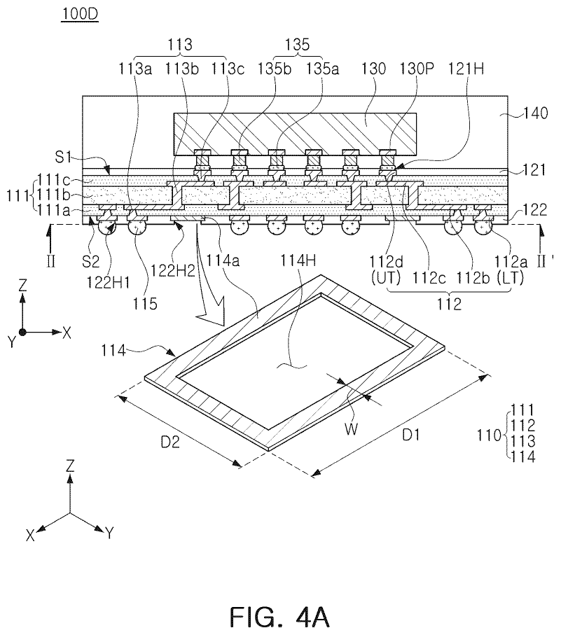

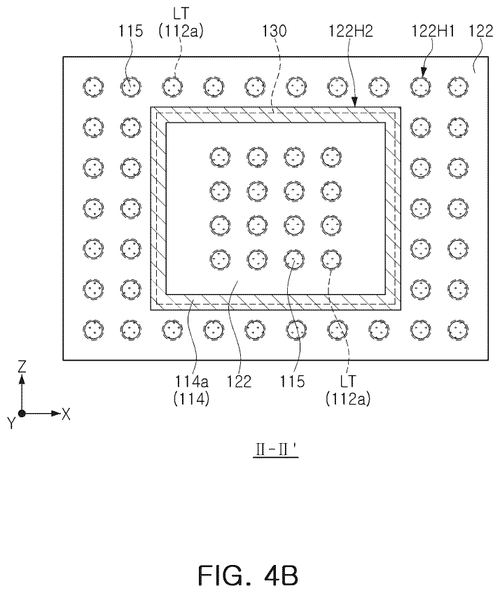

FIG. 4A is a cross-sectional view of a semiconductor package 100D according to some example embodiments, and FIG. 4B is a plan view taken along line II-II′ of FIG. 4A.

Referring to FIGS. 4A and 4B, the semiconductor package 100D of some example embodiments may have the same or similar features as those described with reference to FIGS. 1A to 3, except that the induction heating structure 114 includes a patterned lower pad 114a. In some example embodiments, the lower pad 114a may be patterned according to the design of the interconnection pattern 112, e.g., to be located within a region in which the lowermost interconnection pattern 112a and the lower terminals LT are not disposed. For example, the lower pad 114a may have a circular or polygonal ring shape with a hollow portion 114H. In some example embodiments, the lower pad 114a may have a rectangular ring shape having a horizontal width D1 and a vertical width D2 of about 1000 μm or more. In this case, an interval W between an outer surface and an inner surface of the ring-shaped lower pad may be equal to or substantially equal to or larger than the width of the lower terminals LT. In addition, the lower protective layer 122 may include a through-hole 122H2 exposing at least a portion of the patterned lower pad 114a. In a planar view, the through-hole 122H of the lower protective layer 122 may have a trench shape extending along the shape of the patterned lower pad 114a.

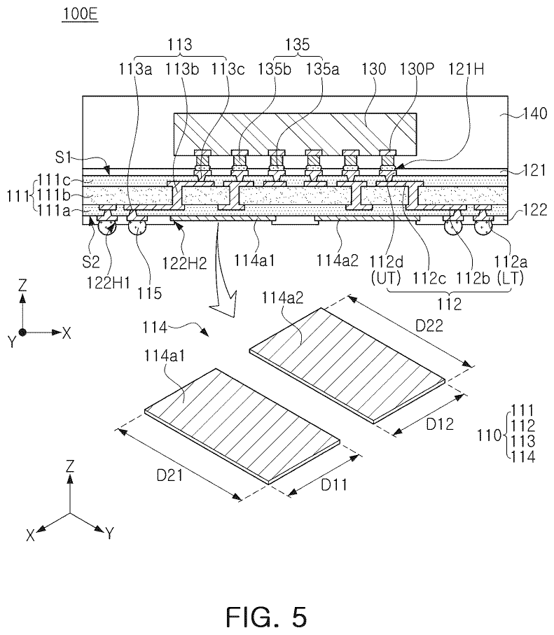

FIG. 5 is a cross-sectional view of a semiconductor package 100E according to some example embodiments.

Referring to FIG. 5, the semiconductor package 100E of some example embodiments may have the same or similar features as those described with reference to FIGS. 1A to 4B, except that the induction heating structure 114 includes a plurality of lower pads 114a1 and 114a2, spaced apart from each other. The induction heating structure 114 may include a first lower pad 114a1 and a second lower pad 114a2, spaced apart from each other in a horizontal direction (e.g., X-direction). The first lower pad 114a1 and the second lower pad 114a2 may be selectively inductively heated by a low-frequency alternating magnetic field of about 500 kHz or less, respectively. For example, a width D11 of the first lower pad 114a1 in a first horizontal direction (X-direction) and a width D21 of the first lower pad 114a1 in a second horizontal direction (Y-direction) may be about 1000 μm or more, for example, within a range of about 1000 μm to about 2000 μm, about 1100 μm to about 2000 μm, about 1200 μm to about 2000 μm, about 1300 μm to about 2000 μm, about 1300 μm to about 1800 μm, about 1300 μm to about 1600 μm, about 1300 μm to about 1500 μm, and the like. In addition, a width D12 of the second lower pad 114a2 in the first horizontal direction (X-direction) and a width D22 of the second lower pad 114a2 in the second horizontal direction (Y-direction) may have a numeral range of about 1000 μm or more, for example, similar to the widths of the first lower pad 114a1 described above.

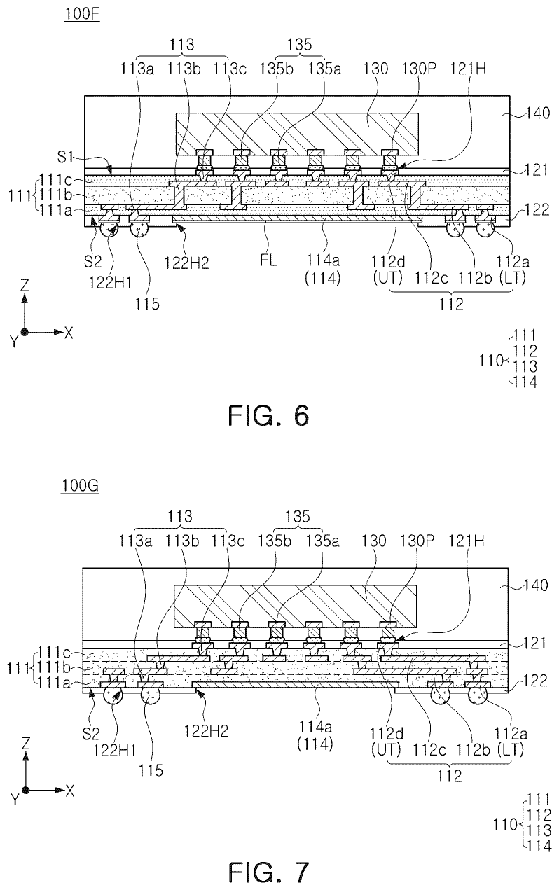

FIG. 6 is a cross-sectional view of a semiconductor package 100F according to some example embodiments.

Referring to FIG. 6, the semiconductor package 100F of some example embodiments may have the same or similar features as those described with reference to FIGS. 1A to 5, except for further including a surface finish layer (FL) covering some surfaces of the induction heating structure 114. In some example embodiments, the substrate 110 may further include a surface finish layer FL covering a lower surface of an exposed lower pad 114a. The surface finish layer FL may be a single or multiple thin film layers, for example, including nickel (Ni) and/or gold (Au). The surface finish layer FL may physically and chemically protect a surface of the lower pad 114a exposed through a through-hole 122H of the lower protective layer 122. Depending on the embodiment, the surface finish layer FL may also be formed between the lower terminals LT and the lower connection bumps 115.

FIG. 7 is a cross-sectional view of a semiconductor package 100G according to some example embodiments.

Referring to FIG. 7, the semiconductor package 100G of some example embodiments may have the same or similar features as those described with reference to FIGS. 1A to 6, except that some components of the substrate 110 are modified. In some example embodiments, the body 111 of the substrate 110 may not include a relatively thick core insulating layer. The plurality of insulating layers 111a, 111b, and 111c may be formed using a photosensitive polymer such as a Photo Imageable Dielectric (PID). For example, the plurality of insulating layers 111a, 111b, and 111c may include a polyimide (PI)-based photosensitive polymer, a polybenzoxazole (PBO)-based photosensitive polymer, a polyhydroxystyrene (PHS)-based photosensitive polymer, a novolak-based photosensitive polymer, a benzocyclobutene (BCB)-based photosensitive polymer, and the like. However, example embodiments are not limited thereto. The plurality of insulating layers 111a, 111b, and 111c may be formed in a greater number of layers (e.g., 4 layers, 5 layers, or the like) than those illustrated in the drawing (3 layers), and boundaries of each layer may be unclear, depending on the process. The plurality of interconnection vias 113a, 113b, and 113c may have a shape of which side surfaces thereof are tapered in the same direction. For example, the plurality of interconnection vias 113a, 113b, and 113c may have a shape tapered toward the second surface S2 of the substrate 110.

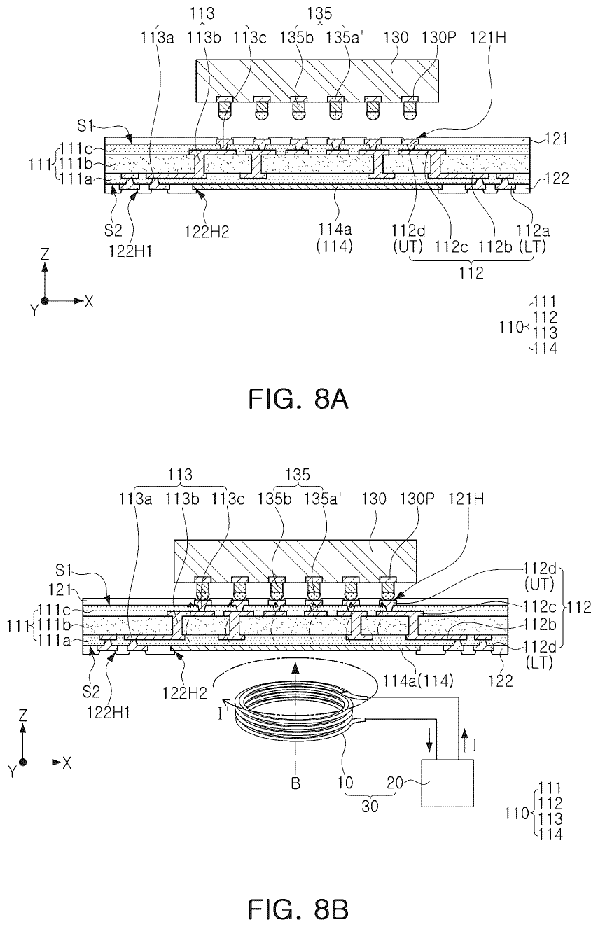

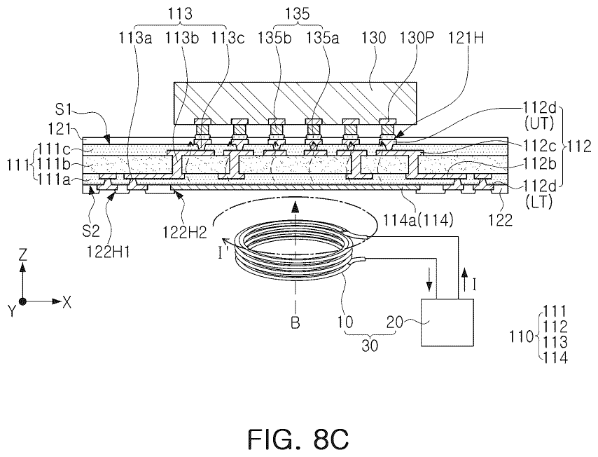

FIGS. 8A to 8C are drawings for illustrating a method of manufacturing a semiconductor package according to some example embodiments.

Referring to FIG. 8A, first, a substrate 110 and a semiconductor chip 130 may be prepared. The substrate 110 may have a first surface S1 and a second surface S2, opposite to each other, and may include upper terminals UT on the first surface S1, lower terminals LT on the second surface S2, and at least one lower pad 114a.

The first surface S1 of the substrate 110 may be covered by an upper protective layer 121. The upper protective layer 121 may include first openings 121H exposing at least a portion of each of the upper terminals UT.

The second surface S2 of the substrate 110 may be covered by a lower protective layer 122. The lower protective layer 122 may include second openings 122H1 exposing at least a portion of each of the lower terminals LT and a through-hole 122H2 exposing at least a portion of the lower pad 114a.

The semiconductor chip 130 may include connection pads 130P and connection bumps 135 respectively disposed on the connection pads 130P. The connection bumps 135 may include a preliminary solder portion 135a′ (which may be referred to as a ‘solder bump’) and a pillar portion 135b. According to some example embodiments, the connection bumps 135 may include only the preliminary solder portion 135a′. The semiconductor chip 130 may be disposed on the first surface S1 of the substrate 110 so that the preliminary solder portion 135a′ is attached to the upper terminals UT of the substrate 110.

Referring to FIG. 8B, the lower pad 114a may be inductively heated using an induction heating tool 30. The induction heating tool 30 may include a coil structure 10 and a power supply device 20. The induction heating tool 30 may further include a cooler configured to cool the coil structure 10, and an infrared camera for measuring a temperature of the lower pad 114a and the upper terminals UT.

The coil structure 10 may be disposed on the second surface S2 of the substrate, adjacent to the lower pad 114a. It may be a coil in which a conductor is wound in multiple layers. The coil structure 10 may be configured so that the power supply device 20 applies an alternating current (I) of about 500 kHz or less to the coil structure 10. An alternating magnetic field (B) may be generated inside the coil structure 10 by the alternating current (I) supplied from the power supply device 20. The alternating magnetic field (B) generates an eddy current (I′) within a lower pad 114a, and the lower pad 114a may be inductively heated by the eddy current (I′). Heat generated by the eddy current (I′) may be conducted to the upper terminals UT, and as a result, a preliminary solder portion 135a′ attached to the upper terminals UT may be heated to a melting temperature. For example, the AC magnetic field is in the range of about 300 kHz to about 400 kHz (e.g., 380 kHz), and the lower pad 114a may be inductively heated to about 300° C. or lower. According to some example embodiments, the lower pad 114a may be heated to about 300° C. or lower, thereby limiting and/or preventing thermal damage to the substrate 110 and the semiconductor chip 130, and/or improving the reliability of the semiconductor package.

Referring to FIG. 8C, a preliminary solder portion 135a′ may be reflowed by heat conducted from the inductively heated lower pad 114a. The solder portion 135a may be fused to the corresponding upper terminals UT respectively by heat conducted from the lower pad 114a.

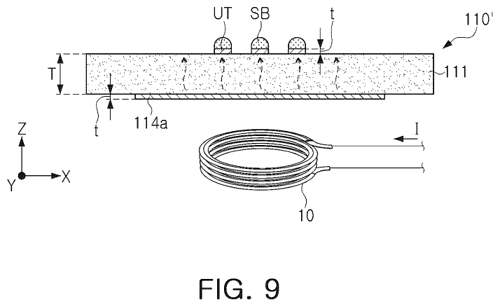

FIG. 9 is a schematic cross-sectional view of a test substrate used in an experimental example.

Referring to FIG. 9, in an experimental example, an alternating current (I) was applied to a coil structure 10 having a diameter of 8 mm under conditions of about 380 kHz, 200 V, and 12 A to inductively heat a test substrate 110′. The test substrate 110′ was prepared to include a body 111, and a lower pad 114a and an upper terminal UT respectively disposed on both sides of the body 111. The body 111 was comprised of FR-4 with a thickness T of about 0.8 mm. The lower pad 114a and the upper terminal UT were respectively formed into a hexahedron having the same horizontal (X-direction) width and vertical (Y-direction) width and a thickness (t) of about 75 μm. A solder ball SB (e.g., 96.5% of Sn, 3% of Ag, 0.5% of Cu) having a melting point of approximately 217° C. was attached to the upper terminal UT. The coil structure 10 was spaced apart from the lower pad 114a by about 0.5 cm. Table 1 shows a heating temperature according to the size of the lower pad 114a and the upper terminal UT in experimental examples. In Table 1, the ‘size’ of the lower pad and upper terminal represents each of the horizontal width and vertical width, and the ‘temperature’ of the lower pad and upper terminal was measured using an infrared camera.

TABLE 1

| | Alternating magnetic field | | Lower pad | | Upper terminal | |
|---|---|---|---|---|---|---|
| | Frequency | Applied time | size | temperature | size | Temperature |
| classification | (kHz) | (min.) | (μm/μm) | (° C.) | (μm/μm) | (° C.) |
| Experimental | 380 | 5 | 1300 | 188 | 100 | 160 |
| Example 1 | | | | | | |
| Experimental | 380 | 5 | 1400 | 266 | 100 | 240 |
| Example 2 | | | | | | |
| Experimental | 380 | 5 | 1500 | 340 | 100 | 310 |
| Example 3 | | | | | | |
| Experimental | 380 | 5 | 1300 | 188 | 50 | 155 |
| Example 4 | | | | | | |
| Experimental | 380 | 5 | 1400 | 266 | 50 | 230 |
| Example 5 | | | | | | |
| Experimental | 380 | 5 | 1500 | 340 | 50 | 305 |
| Example 6 | | | | | | |

Referring to Table 1, the lower pad 114a and the upper terminal UT of Experimental Examples 1 and 4 were heated to a temperature lower than a melting point of the solder ball SB (about 217° C.). The lower pad 114a and the upper terminal UT of Experimental Examples 3 and 6 were heated to a temperature of about 300° C. or higher, which is higher than the melting point of the solder ball SB (about 217° C.). Therefore, in some example embodiments, a minimum width in the horizontal direction (X- and Y-directions) of the lower pad 114a may be formed within a range of about 1300 μm or more and about 1500 μm or less, and the minimum width in the horizontal direction (X- and Y-directions) of the upper terminal UT may be formed within a range of about 100 μm or less and about 50 μm or more. This is only to describe an experimental example for determining the size of the lower pad 114a, and the size of the lower pad 114a applied to some example embodiments is not limited to the numerical range described above.

As set forth above, according to some example embodiments, a semiconductor package having improved reliability may be provided by introducing a low-frequency induction heating structure into a substrate.

In addition, a method of manufacturing a semiconductor package having improved reliability may be provided by reflowing solder bumps using a low-frequency induction heating structure.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The various effects of some example embodiments are not limited to the above description, and may be more easily understood in the course of describing specific embodiments. While some example embodiments have been shown and described above, it will be apparent to those skilled in the art that modifications and variations could be made without departing from the scope of the example embodiments, as defined by the appended claims.

While some example embodiments have been shown and described above, it will be apparent to those skilled in the art that modifications and variations could be made without departing from the scope of the example embodiments as defined by the appended claims.

1. A semiconductor package, comprising:
a substrate including
a body having a first surface and a second surface, the first surface and the second surface opposite to each other,
a plurality of interconnection patterns arranged in a vertical direction within the body,
the plurality of interconnection patterns including upper terminals on the first surface and lower terminals on the second surface, and
an induction heating structure within the body, and the induction heating structure spaced apart from the plurality of interconnection patterns;
an upper protective layer on the first surface of the substrate and the upper protective layer including first openings respectively exposing the upper terminals;
a semiconductor chip on the upper protective layer, and the semiconductor chip including connection pads;
upper connection bumps on the first openings of the upper protective layer, and the upper connection bumps electrically connecting the connection pads and the upper terminals;
a lower protective layer on the second surface of the substrate, and the lower protective layer including second openings respectively exposing the lower terminals and a through-hole exposing at least a portion of the induction heating structure; and
lower connection bumps on the second openings of the lower protective layer, and the lower connection bumps electrically connected to the lower terminals,
wherein the induction heating structure includes
at least one lower pad exposed through the through-hole, and
a first width of the at least one lower pad in a horizontal direction is greater than a second width of each of the lower terminals in the horizontal direction.

2. The semiconductor package of claim 1, wherein the at least one lower pad overlaps the upper terminals and the upper connection bumps in the vertical direction.

3. The semiconductor package of claim 1, wherein the at least one lower pad overlaps a lowermost interconnection pattern among the plurality of interconnection patterns in the horizontal direction.

4. The semiconductor package of claim 1, wherein a third width of each of the upper terminals in the horizontal direction is smaller than the second width.

5. The semiconductor package of claim 4, wherein
the first width is within a range of 1000 μm to 2000 μm,
the second width is within a range of 100 μm to 400 μm, and
the third width is within a range of 10 μm to 100 μm.

6. The semiconductor package of claim 1, wherein a thickness of the at least one lower pad in the vertical direction is equal to a thickness of each of the lower terminals in the vertical direction.

7. The semiconductor package of claim 1, wherein the at least one lower pad has a circular or polygonal plate shape.

8. The semiconductor package of claim 1, wherein the at least one lower pad has a hollow circular or polygonal ring shape.

9. The semiconductor package of claim 8, wherein an interval between an outer surface and an inner surface of the at least one lower pad is equal to or greater than the second width.

10. The semiconductor package of claim 8, wherein, in a planar view, the through-hole of the lower protective layer has a trench shape extending along the at least one lower pad.

11. The semiconductor package of claim 1, wherein
the induction heating structure further comprises
at least one upper pad on the at least one lower pad, and
a heat-conduction via connecting the at least one lower pad and the at least one upper pad.

12. The semiconductor package of claim 11, wherein a fourth width of the at least one upper pad in the horizontal direction is smaller than the first width.

13. The semiconductor package of claim 11, wherein the at least one upper pad has a ring shape extending along an edge of the at least one lower pad.

14. The semiconductor package of claim 11, wherein
the substrate further comprises
interconnection vias connecting the plurality of interconnection patterns to each other, and
a diameter of the heat-conduction via is greater than a diameter of each of the interconnection vias.

15. The semiconductor package of claim 1, wherein the substrate further comprises a surface finish layer covering a surface of the at least one lower pad exposed through the through-hole.

16. The semiconductor package of claim 1, wherein the upper connection bumps and the lower connection bumps comprise at least one of tin (Sn) or an alloy of tin (Sn).

17. A semiconductor package, comprising:
a substrate including
a body including a first surface and a second surface, the first surface and the second surface opposite to each other,
a plurality of interconnection patterns arranged in a vertical direction within the body,
the plurality of interconnection patterns including upper terminals on the first surface and lower terminals on the second surface, and
an induction heating structure within the body, and the induction heating structure spaced apart from the plurality of interconnection patterns;
an upper protective layer on the first surface of the substrate;
a semiconductor chip on the upper protective layer, and the semiconductor chip including connection pads;
upper connection bumps between the substrate and the semiconductor chip, and the upper connection bumps electrically connecting the connection pads and the upper terminals; and
lower connection bumps on the second surface of the substrate, and the lower connection bumps electrically connected to the lower terminals,
wherein the induction heating structure includes
at least one lower pad overlapping a lowermost interconnection pattern among the plurality of interconnection patterns in a horizontal direction,
the at least one lower pad is electrically insulated from the plurality of interconnection patterns, and
a width of the at least one lower pad in the horizontal direction is greater than a width of each of the lower terminals in the horizontal direction.

18-20. (canceled)
